(19) United States
(12) Patent Application Publication
(10) Pub. No.: US 2022/0139918 A1
(43) Pub. Date: May 5, 2022

(54) Novel Three-Dimensional DRAM Structures

(71) Applicant: Sang-Yun Lee, Portland, OR (US)

(72) Inventor: Sang-Yun Lee, Portland, OR (US)

(73) Assignee: Sang-Yun Lee, Hillsboro, OR (US)

(21) Appl. No.: 17/084,420

(22) Filed: Oct. 29, 2020

(51) Int. Cl. H01L 27/108; H01L 29/78

(52) U.S. Cl. CPC H01L 27/10808; H01L 29/7827

(57) ABSTRACT

Novel three-dimensional DRAM structures are disclosed, together with methods of making the same. Each DRAM cell comprises a vertical transistor and a storage capacitor stacked vertically. Storage capacitors are arranged in a rectangular pattern in the array of DRAM cells. This arrangement improves the area efficiency of storage capacitors over honeycomb type. A first embodiment of the present disclosure uses cup-shaped storage capacitors. The exterior of the cup as well as the interior may contribute to the capacitance. In a second embodiment, a single capacitor pillar forms the internal electrode of each storage capacitor. A third embodiment employs double-pillar storage capacitors. Common to all embodiments are options to dispose contact plugs between vertical transistors and storage capacitors, dispose an etch-stop layer over the gate of vertical transistors, dispose one or more mesh layers for storage capacitors, and widen semiconductor pillars within available space in bit-line direction.

### TECHNICAL FIELD

The present disclosure relates generally to the technical field of a semiconductor memory device, more specifically structures and methods for dynamic random access memories (“DRAMs”).

### BACKGROUND

DRAM comprises an array of unit memory cells, each comprising one transistor such as a MOSFET (metal-oxide-semiconductor field-effect transistor), and one storage capacitor. In general, the transistor has one side of the channel connected to an external circuit line (called a bit line) and the other side to one electrode (called a storage node) of the capacitor. The transistor gate is connected to another external circuit line (called a word line), and the other electrode of the capacitor is connected to a reference voltage. The transistor, which works as an access switch, charges or discharges the storage node. Depending on whether the storage node holds an electric signal charge, the memory cell stays in one of its binary states.

As the technology moves to a more advanced node, the size of DRAM cell shrinks in order to pack more memory cells in a given area. However, a storage capacitor needs to maintain its charge-holding capacity in order to meet a required refresh rate. A memory controller issues refresh commands at the interval of a given refresh time. The minimum refresh rate for a particular DRAM architecture is standardized by JEDEC (Joint Electron Device Engineering Council). For DDR3 (Double Data Rate third generation), the minimum refresh rate is 7.8 microseconds.

As DRAM cell size shrinks, the lateral area for the storage capacitor shrinks as well. The capacitance of the storage capacitor per unit surface area of its electrodes does not increase because the thickness of the dielectric between the capacitor's electrodes is maintained at a certain minimum in order to prevent leakage current through the dielectric and to thereby meet a required refresh rate. Then, the storage capacitor needs to grow taller in order to maintain its overall surface area, hence its total capacitance, within the limited lateral area.

In advanced technology nodes, DRAM cell layout is optimized or enlarged to ensure the required refresh rate. Cell size is limited by the size and arrangement of the storage capacitors rather than by the transistors or interconnects. DRAM cell size is commonly stated as “6 F²” (six F-squares) where “F” is the minimum dimension of the technology used to manufacture the DRAM product. However, the actual cell size is usually in the range of 8 to 10 F², enlarged in order to accommodate a storage capacitor of reasonable capacitance for the required fresh rate.

Area efficiency of storage capacitors has been improved with the adoption of different layout styles. For example, FIGS. 1A-B illustrate two types of capacitor arrangements commonly used for DRAM products. In FIG. 1A, copies of a storage capacitor 135 are made in a pattern resembling a square. Dashed-line box S connecting the centers of capacitors demonstrates a checker-type arrangement of the capacitors. Although capacitors are drawn more or less like squares in an actual layout, the corners of capacitors are rounded off in manufactured chips due to an optical effect, and each capacitor takes a circular shape in advanced technology nodes. In FIG. 1B, copies of storage capacitor 135 are made in a pattern resembling a hexagon. Dashed-line hexagon H connecting the centers of capacitors demonstrates a honeycomb-type arrangement of the capacitors.

A honeycomb-type arrangement of storage capacitors is used in advanced DRAM products rather than a checker-type arrangement because the former increases area efficiency by approximately 15% over the latter. In other words, a honeycomb-type layout increases storage capacitance in a given cell area by approximately 15%, compared to a checker-type layout. It is worth noting the difference in the area unoccupied by capacitors. The wasted area is smaller for the honeycomb-type layout than for the checker-type layout. This results in the above-mentioned improvement in the area efficiency.

Storage capacitors of the same capacitance can be constructed on a smaller lateral area for honeycomb type than for checker type with the same capacitor height. Therefore, a smaller cell size, ultimately a smaller chip size, can be achieved through the use of honeycomb-type arrangement of storage capacitors due to its improved area efficiency. A product of a smaller chip size can pack more chips on a given wafer and can achieve a higher percentage yield, thereby lowering the cost per chip. Conversely, storage capacitors of the same capacitance can be constructed with a smaller capacitor height for honeycomb type than for checker type on the same lateral area. Capacitor height is an important factor in manufacturability and thus yield of a DRAM product. Therefore, a honeycomb-type layout on the same cell size as a checker-type layout can result in a lower cost per chip.

### SUMMARY

Novel three-dimensional (3D) DRAM structures and methods of making the same are described. The storage capacitors of the present disclosure are shaped to improve the area efficiency by approximately 15% over the honeycomb type. Memory cell sizes are as small as 5 F² under the various embodiments of the present disclosure, although many of them may be quoted as “4 F²” in the industry. Therefore, the noble structures will be suitable for high-density DRAM products, especially for 3D DRAM products.

In the DRAM structures of the present disclosure, vertical transistors and storage capacitors are stacked vertically. Vertical transistors used in an array of DRAM cells are spaced wider in bit-line direction than in word-line direction. This is to have gates of vertical transistors separated in bit-line direction but connected in word-line direction without employing a mask in patterning the gates. Storage capacitors can be made longer in bit-line direction than in word-line direction. Features of the present disclosure include schemes to reduce contact resistance between vertical transistors and storage capacitors. Options are described that increase capacitance of each DRAM cell, improve manufacturing yield, and/or improve operating margin, with some of the options increasing cell size slightly. These schemes and options are applicable to any of the embodiments of the present disclosure.

In accordance with a first embodiment of the present disclosure, storage capacitors having a rectangular shape in a horizontal cross section are disposed over vertical transistors. A smallest cell size in the first embodiment is 5 F². The internal electrodes of the storage capacitors have a cup shape in a vertical cross section. A top portion of the semiconductor pillars with which the vertical transistors are constructed is surrounded by the internal electrodes to reduce the contact resistance between the semiconductor pillars and the internal electrodes.

An etch-stop layer may be disposed over the gate of vertical transistors for ease of manufacturing and to ensure that the internal electrodes are separated from the gate. Contact plugs may be disposed on, and surround a top portion of, the semiconductor pillars in order to further reduce contact resistance between the storage capacitors and the vertical transistors. One or more mesh layers may be disposed on a portion of the exterior surface of capacitor cups to support, and prevent the toppling of, the storage capacitors which are generally very tall, often at least 10 times as tall as vertical transistors. Storage capacitors may be widened in bit-line direction, thus increasing the cell size to 6 F² or more, for a longer refresh time, a more robust operation, or a higher percentage yield. In such a case, the semiconductor pillars may also be widened by up to the same amount in bit-line direction.

A second embodiment of the present disclosure employs pillar-shaped internal electrodes for storage capacitors. A smallest cell size in the second embodiment is 5 F². The capacitor pillars have a rectangular shape in a horizontal cross section. Capacitor pillars surround a top portion of semiconductor pillars, which serves to reduce the contact resistance between the semiconductor pillars and the capacitor pillars. For the second embodiment, like the first, an etch-stop layer may be disposed over the gate of vertical transistors, contact plugs surrounding a top portion of semiconductor pillars may be disposed between storage capacitors and vertical transistors, at least one mesh layer may be disposed on a portion of sidewall of capacitor pillars, and storage capacitors may be widened in bit-line direction with optional widening of the semiconductor pillars by the same or lesser amount.

In a third embodiment of the present disclosure, each DRAM cell accommodates two capacitor pillars. A smallest possible cell size in this case, although larger than the minimum of the other embodiments, involves capacitor pillars of circular shape. For a rectangular storage capacitor, the cell size is even larger, but there are benefits of higher capacitance per cell and/or higher percentage yield. A contact plug is typically required in order to dispose a double-pillar storage capacitor over a vertical transistor, particularly when the semiconductor pillar of the vertical transistor is of a minimum size. For the third embodiment, as in the other two, an etch-stop layer may be disposed over the gate of vertical transistors, and at least one mesh layer may be disposed on a portion of sidewall of capacitor pillars. Semiconductor pillars may be widened in bit-line direction without increasing cell size or capacitor pillar size. Particularly in such a case, contact plugs may not be disposed under capacitor pillars.

This Summary is provided to introduce a selection of concepts in a simplified form that are further described below in Detailed Description. This Summary is not intended to identify key or essential features of the claimed subject matter, nor is it intended to be used as an aid in determining the scope of the claimed subject matter. Furthermore, the structures and methods disclosed herein may be implemented in any means and/or combinations for achieving various aspects of the present disclosure. Other features will be apparent from the accompanying drawings and from the detailed description that follows. Accordingly, the specification and drawings are to be regarded in an illustrative rather than a restrictive sense.

### BRIEF DESCRIPTION OF THE DRAWINGS

Example embodiments are illustrated by way of example and not limitation in the figures of the accompanying drawings, in which like references indicate similar elements.

FIG. 1A (prior art) illustrates a checker-type arrangement of storage capacitors.

FIG. 1B (prior art) illustrates a honeycomb-type arrangement of storage capacitors.

FIG. 2A illustrates a rectangular-type arrangement of rectangular storage capacitors in accordance with embodiments of the present disclosure.

FIG. 2B illustrates a simplified layout view of memory cells with the storage capacitors of FIG. 2A in accordance with a first embodiment of the present disclosure.

FIG. 2C is a cross-sectional view of FIG. 2B along line A-A′ in accordance with the first embodiment of the present disclosure.

FIG. 2D is a cross-sectional view of FIG. 2B along line B-B′ in accordance with the first embodiment of the present disclosure.

FIG. 2E illustrates an alternative structure with a wider semiconductor pillar for the vertical transistor within the same cell area in the first embodiment of the present disclosure.

FIGS. 2F-I illustrate intermediate structures in a sequence of steps for constructing the memory cells of FIGS. 2C-D in accordance with the first embodiment of the present disclosure.

FIG. 2J illustrates an alternative structure in which only the interior surface of the cup-shaped internal electrode contributes to the capacitance of storage capacitors.

FIG. 2K illustrates an alternative structure with an etch-stop layer disposed under the storage capacitors in the first embodiment of the present disclosure.

FIG. 2L illustrates an alternative structure incorporating a mesh layer that supports the storage capacitors in the first embodiment of the present disclosure.

FIG. 2M illustrates a flowchart with key process steps for constructing the DRAM structure in the first embodiment of the present disclosure. Included is a non-exhaustive list of exemplary process options.

FIG. 3A illustrates a cross-sectional view of FIG. 2B along line A-A′ for an alternative structure having contact plugs between vertical transistors and storage capacitors in the first embodiment of the present disclosure.

FIG. 3B illustrates an alternative structure with an etch-stop layer and contact plugs in the first embodiment of the present disclosure.

FIGS. 3C-D illustrate intermediate structures in a sequence of steps for constructing the memory cells of FIG. 3A in the first embodiment of the present disclosure.

FIG. 4A illustrates a simplified layout view of memory cells with the storage capacitors of FIG. 2A in accordance with a second embodiment of the present disclosure.

FIG. 4B is a cross-sectional view of FIG. 4A along line A-A′ in accordance with the second embodiment of the present disclosure.

FIG. 4C is a cross-sectional view of FIG. 4A along line B-B′ in accordance with the second embodiment of the present disclosure.

FIG. 4D illustrates an alternative structure with the semiconductor pillars widened in bit-line direction in accordance in the second embodiment of the present disclosure. When the semiconductor pillars are widened, contact plugs between storage capacitors and vertical transistors are optional.

FIGS. 4E-G illustrate intermediate structures in a sequence of steps for constructing the memory cells of FIGS. 4B-C in accordance with the second embodiment of the present disclosure.

FIG. 5A illustrates a simplified layout view of memory cells with the storage capacitors in accordance with a third embodiment of the present disclosure.

FIG. 5B is a cross-sectional view of FIG. 5A along line A-A′ in the third embodiment of the present disclosure.

FIG. 5C is an alternative structure of the third embodiment in which the vertical transistors is made wider in bit-line direction within the same cell area.

The drawings referred to in this description should be understood as not being drawn to scale, except if specifically noted, in order to show more clearly the details of the present disclosure Like reference numbers in the drawings indicate like elements throughout the several views Like fill patterns in the drawings indicate like elements throughout the drawings, in the absence of like reference numbers. Other features and advantages of the present disclosure will be apparent from accompanying drawings and from the detailed description that follows.

### DETAILED DESCRIPTION

Structures and methods for a novel three-dimensional DRAM cell are disclosed. In the following description, for the purposes of explanation, numerous specific details are set forth in order to provide a thorough understanding of the various embodiments. However, it will be evident that one skilled in the art may practice various embodiments within the scope of this disclosure without these specific details.

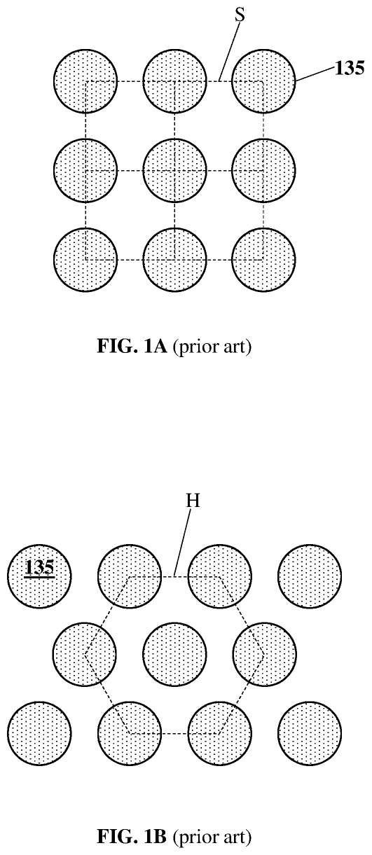

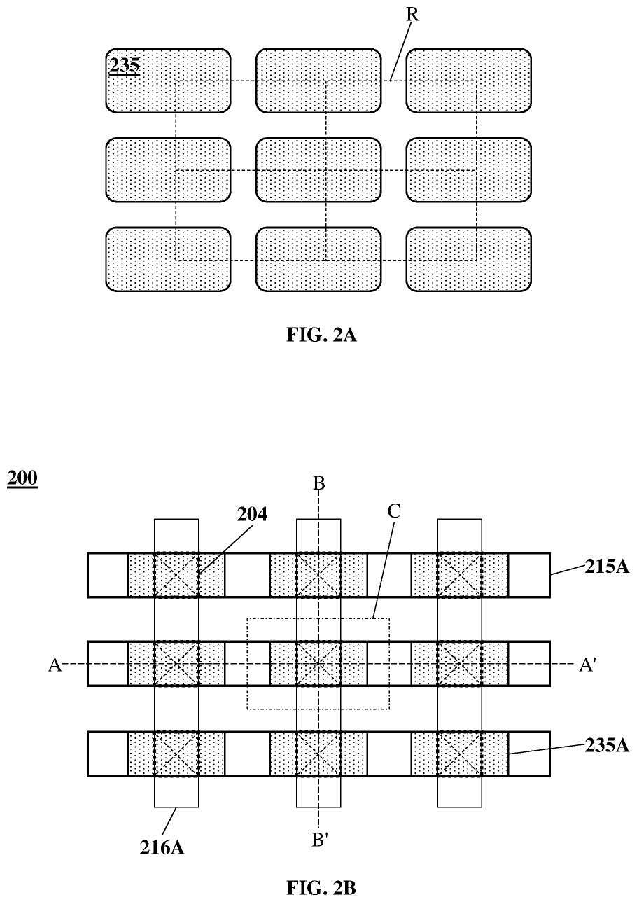

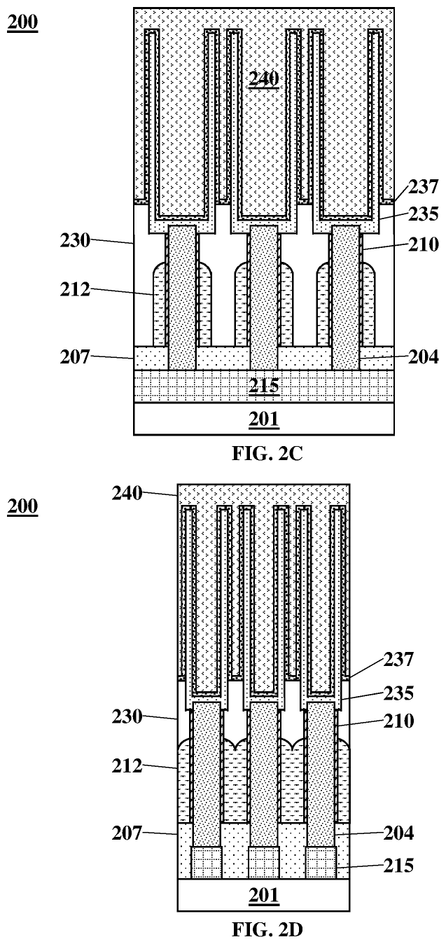

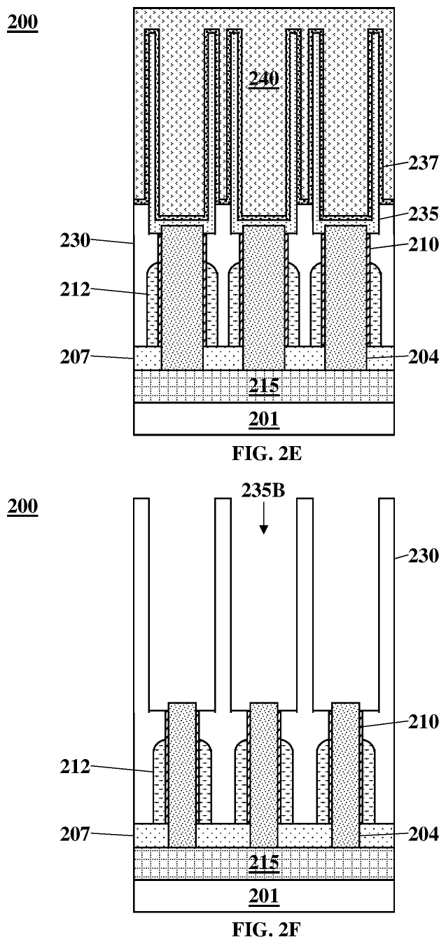

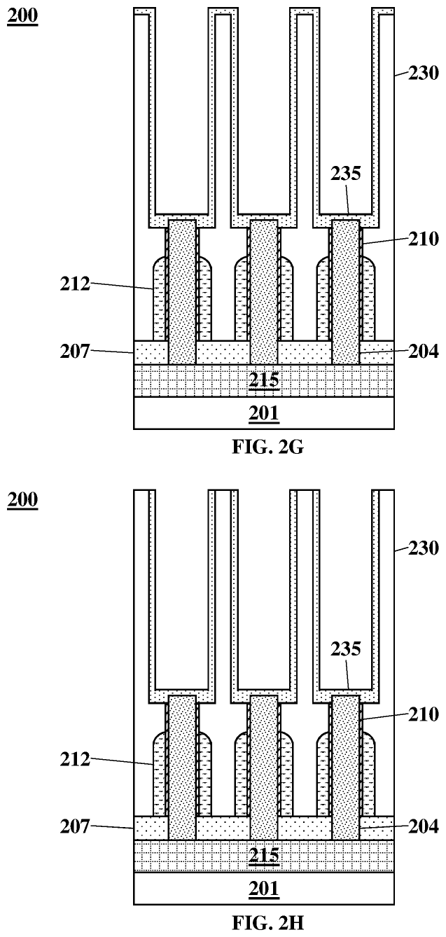

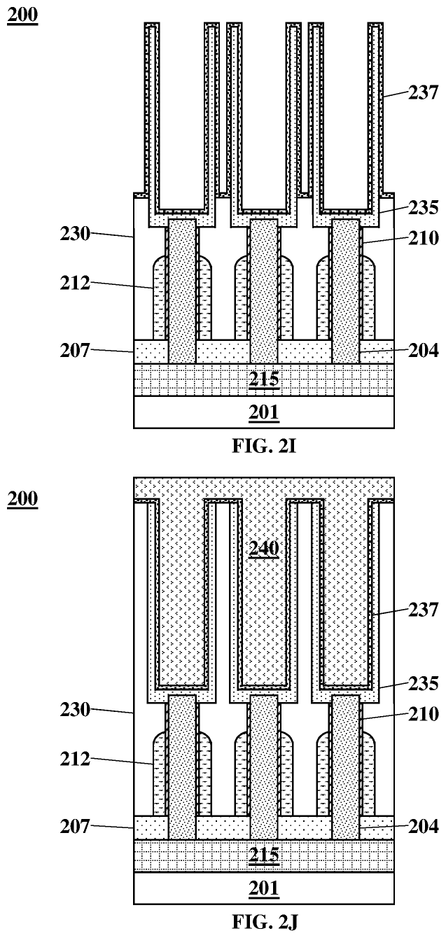

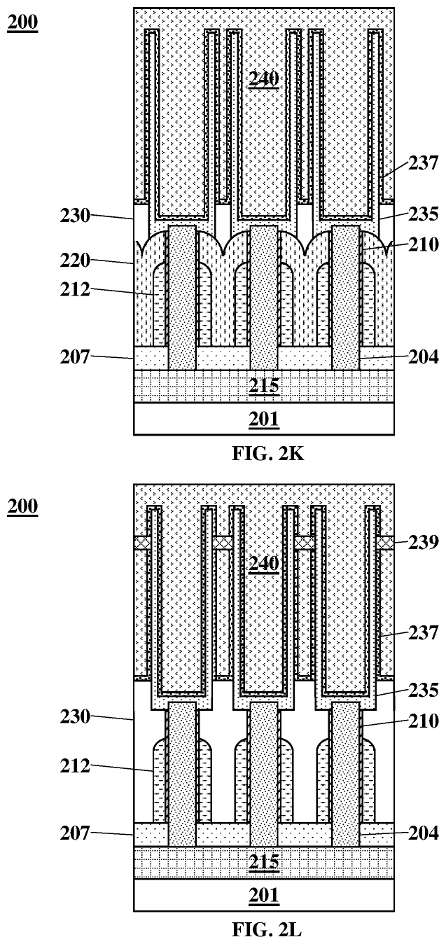

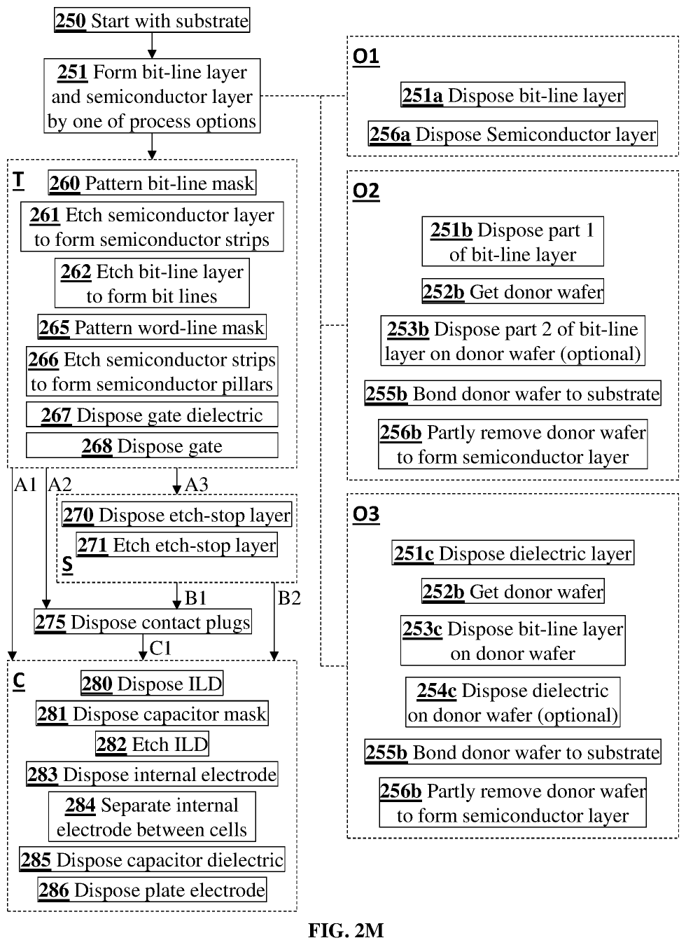

FIG. 2A illustrates an arrangement of rectangular storage capacitors duplicated in an array in accordance with embodiments of the present disclosure. Here, rounded rectangle 235 represents the approximate outline of the respective internal electrodes near the bottom of storage capacitors in a finished product. Dashed-line box R demonstrates the rectangular arrangement of capacitors. Because a longer side of a rectangular capacitor runs parallel with that of an immediate neighbor, the optical effect which tends to round off the corners does not round off the overall shape of rectangles as much as those of squares drawn in minimum geometries of the technology used in manufacturing. With the same spacing between shapes, the wasted area between rectangles of FIG. 2A appears smaller than that between circles of FIGS. 1A-B. Indeed, the percentage of area occupied by the shape within a unit cell is approximately 15% larger for rectangles in rectangular arrangement of FIG. 2A than for circles in honeycomb arrangement of FIG. 1B. A rectangular shape may turn out to be a rounded rectangle, oval, or ellipse depending on optical effect. Therefore, as used throughout the present disclosure, the words “rectangle” and “rectangular” should be understood to include various diversions such as “rounded rectangle,” “oval,” or “ellipse.”

FIG. 2B illustrates a simplified layout view 200 of DRAM cells in an array in accordance with a first embodiment of the present disclosure. Shown in this layout view are bit-line layout 215A, word-line layout 216A, and capacitor layout 235A. Semiconductor pillars 204, outlined with a thick dotted line in FIG. 2B (and in other layout views), are not drawn in layout, but defined by the intersection of bit-line layout 215A and word-line layout 216A. As described in subsequent paragraphs, formation of semiconductor pillars involves two sets of photolithography and etching: one set with a bit-line mask generated from 215A and another with a word-line mask generated from 216A. Although an intersection of two perpendicular rectangles of the same width would result in a square, semiconductor pillars 204 take a circular shape in finished products as a result of effects of photolithography and etching.

Line A-A′ indicates a bit-line direction while line B-B′ indicates a word-line direction. In the subsequent figures (FIGS. 2C-D), cross-sectional views are illustrated, one along line A-A′ and another along line B-B′. The space between semiconductor pillars 204 is wider along the bit-line direction, typically at least 1.5 F wide, than along the word-line direction, typically 1.0 F wide. The space between storage capacitors as laid out (with a label of 235A) is typically 1.0 F in both word-line and bit-line directions. On manufactured chips, the space between storage capacitors is much narrower due to an etch effect employed specifically to increase the size of the storage capacitors. Storage capacitors 235 of FIG. 2A are drawn larger than capacitor layout 235A of FIG. 2B to specifically illustrate such narrowing.

FIG. 2C illustrates a cross-sectional view of the layout in FIG. 2B along bit-line direction A-A′. The vertical transistors (not labeled) comprising semiconductor pillars 204, gate dielectric 210, and gate 212 are separated at gate along the bit-line direction.

FIG. 2D illustrates a cross-sectional view of the layout of FIG. 2B along word-line direction B-B′. Bit lines 215 are patterned simultaneously with semiconductor pillars 204, using a bit-line mask (not shown but based on bit-line layout 215A). A first phase in an etching step cuts through a semiconductor layer (not shown) and leaves semiconductor strips (not shown) stretching along bit-line direction A-A′. A second phase of the etching step patterns a bit-line layer (not shown) into bit lines 215. The semiconductor strips are patterned again with a word-line mask (not shown but based on word-line layout 216A), and become semiconductor pillars 204 taking a circular cross section upon the second patterning. After the first patterning, bit lines 215 and the semiconductor layer are of the same width. Upon the second patterning which is selective to the bit lines and substrate 201 (or a top layer thereof), semiconductor pillars become slightly narrower than bit lines.

The vertical transistors are connected at gate along the word-line direction, because a gate material (not shown) is sufficiently thick to fill the narrow space between semiconductor pillars 204 along word-line direction and remains merged upon the subsequent etching of the gate material. Along the bit-line direction, however, the thickness of the gate material is sufficiently thin not to fill the wider space between semiconductor pillars and result in gate 212 separated upon etch of the gate material.

Box C of FIG. 2B illustrates a unit cell of the first embodiment. A minimum cell area is usually 5 F², with a pitch of 2.5 F in bit-line direction and 2.0 F in word-line direction, or in other words, with a spacing of 1.5 F for word-line layout 216A and 1.0 F for bit-line layout 215A. However, FIG. 2B is drawn to illustrate 6 F², with the unit cell spanning 3.0 F in bit-line direction. The storage capacitors are 2.0 F wide in bit-line direction. The wider bit-line pitch may be utilized for different purposes.

In one approach, the extra space may be given to the spacing between semiconductor pillars while keeping the width thereof at 1.0 F in all directions. It will result in wider spacing between gates 212 of vertical transistors along bit-line direction. This in turn increases the spacing between word lines formed by the merger of the gates along word-line direction. Larger word-line spacing reduces the coupling between word lines when cells of one word line are selected and those of a neighboring word line are deselected, thus increasing the operating margin of the product. In another approach, the extra space resulting from wider pitch of semiconductor pillars may be given to the semiconductor pillars, like a first alternative structure shown in FIG. 2E. Wider semiconductor pillars will increase the driving capability of the vertical transistors, improving the operating margin and/or speed of the product. An intermediate approach may be used by using the extra space partly for larger word-line space and partly for wider semiconductor pillars to optimize the product among its speed, operating margin, and yield.

FIGS. 2F-I illustrate intermediate structures in a sequence of steps resulting in those of FIGS. 2C-D. Cross sections are shown along bit-line direction only. Those along word-line direction would be apparent to one skilled in the art, by comparing the cross sections of intermediate structures with FIG. 2C in light of FIG. 2D. Process steps as shown in FIG. 2M will be referred to while describing them in reference to FIGS. 2F-I.

A first block of steps for constructing the novel DRAM structures of the present disclosure is the construction of vertical transistors. In FIG. 2M, steps of 250, 251, and those within box T are involved in the construction of vertical transistors. The process starts with a substrate (step 250 of FIG. 2M), which may have a circuitry built on it and a planarized dielectric layer. The circuitry usually functions to communicate, for a DRAM operation, with the DRAM structure built over the substrate in subsequent process steps. The circuitry may contain one or more blocks of volatile memories such as SRAM (static random access memory), CAM (content-addressable memory), and/or registers, and NVM (nonvolatile memory) such as antifuse and/or flash. An NVM block typically serves as a permanent storage for configurations of the DRAM structure and fine tuning of the DRAM operation. Volatile memory blocks typically serve as temporary storages, shadowing the NVM contents for a high-speed DRAM operation. Configurations of DRAM structure may include how faulty DRAM cells found during manufacturing or field operation are replaced with redundant DRAM cells or other volatile memory cells such as SRAM, CAM, or registers, whether the DRAM should function in a pipeline, burst, or other mode, whether a word size should be e.g. 2, 4, 8, or more bytes, and whether or not a word includes ECC (error correction code) bits. Fine tuning of DRAM operation may include the optimization of timing relationships between various signals for the DRAM operation and of several bias levels such as word-line-on bias, word-line-off bias, and bit-line pre-charge level for read.

On the substrate, a bit-line layer and a semiconductor layer are disposed (step 251 of FIG. 2M) with any of the process options shown exemplarily in boxes O1, O2, and O3 of FIG. 2M. Box O1 represents a case in which the bit-line layer and the semiconductor layers are directly disposed on the substrate (steps 251a and 256a of FIG. 2M), with any of the methods known in the art, such as CVD (chemical vapor deposition), ALD (atomic layer deposition), and particularly for the semiconductor layer, epitaxy.

Alternatively, the semiconductor layer, optionally in conjunction with the bit-line layer, may come from a donor wafer bonded to the substrate (as in box O2 or O3 of FIG. 2M). A typical practice is to dispose a bit-line layer on the substrate (step 251b in box O2 of FIG. 2M). Optionally, the bit-line layer on the substrate may constitute a first part of the bit-line layer, and a second part of bit-line layer may be disposed on the donor wafer (step 253b of FIG. 2M). The donor wafer is flipped over and bonded to the substrate (step 255b of FIG. 2M). Majority of the donor wafer is then removed (step 256b of FIG. 2M), leaving a semiconductor layer on the bit-line layer. The partial removal of the donor wafer after bonding may be performed by a polishing or by a cleavage of the major part of the donor wafer from the substrate for later reuse. A bit-line layer disposed on the substrate and/or the donor wafer is a conductor and is involved in wafer bonding. For this reason, it is also called “conductive bonding layer.”

A somewhat unusual but feasible method of forming bit-line layer and semiconductor layer on the substrate is contained in box O3 of FIG. 2M. A dielectric layer is disposed on the substrate (step 251c of FIG. 2M). On a donor wafer (step 252b of FIG. 2M), bit-line layer is disposed (step 253c of FIG. 2M). A dielectric layer of a material which is the same as or similar to that of the dielectric layer disposed on the substrate may optionally be disposed (step 254c of FIG. 2M) on the bit-line layer. Then, bonding and partial removal of the donor wafer are performed (step 256b of FIG. 2M), as in the manner described in reference to those of box O2.

After the bit-line layer and the semiconductor layer are formed on the substrate with any of the process options described in the preceding paragraph or with any of the variations thereof, a bit-line mask is patterned (step 260 of FIG. 2M) on the semiconductor layer, based on bit-line layout 215A of FIB. 2B. The semiconductor layer is etched (step 261 of FIG. 2M) in a first phase with the patterned bit-line mask to form a plurality of semiconductor strips. Either the semiconductor strips or the bit-line mask will serve as a mask for etching the bit-line layer in a second phase to form a plurality of bit lines. Subsequently, a word-line mask is patterned (step 265 of FIG. 2M) on the semiconductor strips. An etch step would transform the semiconductor strips into a plurality of semiconductor pillars (step 266 of FIG. 2M). A dielectric film (shown as 207 in FIGS. 2C-L) is disposed (not mentioned in FIG. 2M) on the substrate up to a certain bottom portion of the semiconductor pillars. Disposition of dielectric film 207 would typically comprise disposition of a dielectric layer, planarization, and partial etch-back. The dielectric film isolates the subsequently formed transistor gate 212 from bit-line 215.

A gate dielectric 210 is disposed (step 267 of FIG. 2M) on the semiconductor pillars. The gate dielectric is typically disposed after dielectric film 207 is disposed, but it may also be disposed prior to the dielectric film, particularly when the gate dielectric and the dielectric film are of completely different materials. Disposition of gate on the gate dielectric (step 267 of FIG. 2M) involves a sequence of steps. A gate material (not shown) such as polysilicon or a certain metal is disposed, and is subjected to an anisotropic etch. The anisotropic etch with a sufficient over-etch leaves a spacer-like piece of the gate material on the sidewall of semiconductor pillars up to a certain top portion of the semiconductor pillars, forming gate 212 of vertical transistors. The completion of vertical transistor formation is followed by storage capacitor formation with several optional steps in-between.

In FIG. 2F, an inter-layer dielectric (ILD) 230 is disposed (step 280 in box C of FIG. 2M) after forming gate 212 of vertical transistors, transitioning from the last step of box T along arrow A1 in FIG. 2M. Then a capacitor mask (not shown but based on 235A of FIG. 2B) is used (step 281 in box C of FIG. 2M) to etch the ILD (step 282 in box C of FIG. 2M) for the formation of capacitor holes 235B. Although only one hole is indicated in the figure by label 235B, all holes in ILD 230 are formed simultaneously and serve the same purpose of containing storage capacitors. Note that a top portion of semiconductor pillars is exposed at the bottom of the holes. Step 282 needs to be a timed etch to ensure that gate 212 is not exposed and separated from internal electrode 235 with a sufficient margin. As mentioned earlier, the lateral size of capacitor holes 235B is larger than that of capacitor layout 235A as a result of an intentional isotropic over-etching of dielectric layer 230.

Subsequently, as shown in FIG. 2G, a material for internal electrode 235 is disposed (step 283 in box C of FIG. 2M). Note that the internal electrode has a cup shape within the capacitor holes in this embodiment. Note also that the internal electrode surrounds a top portion of semiconductor pillars 204. This enhances the contact area, and thereby reduces the contact resistance, between the vertical transistors and the storage capacitors.

The internal electrode is separated between memory cells (step 284 in box C of FIG. 2M), as shown in FIG. 2H. The separation of internal electrode involves a few operations. An example would be firstly to fill the cup interior with a material such as photoresist, undoped oxide, or some other material having a different chemical property than ILD 230 and internal electrode 235. Then, the cup-filling material is etched back until the internal electrode is exposed at the top of the cup between cells, the internal electrode at the top is removed, and the cup filler is cleared off from the cup interior. Optionally, the chemistry of removing the cup-filling material may be chosen to have ILD 230 removed as well but preferably at somewhat slower etch rate than the cup filler. Then, ILD 230 will be removed down to a bottom portion of the cup exterior simultaneously with a complete removal of the cup-filling material from the cup interior. Or, ILD 230 may be etched back separately after the cup-filling material is cleared off from the cup interior, particularly when ILD 230 and the cup filler are of materials of different chemical property or the removal of the cup filler is highly selective against ILD 230.

Subsequent to the separation of internal electrode, capacitor dielectric 237 is disposed (step 285 in box C of FIG. 2M) to result in the structure depicted in FIG. 2I if ILD 230 is partly removed from the cup exterior of internal electrode 235. With plate electrode 240 disposed (step 286 in box C of FIG. 2M), the structure depicted in FIGS. 2C-D results. If ILD 230 is not removed from the cup exterior, a second alternative structure of the first embodiment as shown in FIG. 2J will result. Although not shown in any of the figures of the present disclosure, the plate electrode is usually patterned to allow interconnect lines to be conductively coupled to various portions of the DRAM product, such as for coupling the plate electrode to a reference voltage supplied from a circuitry built for a DRAM operation.

FIG. 2K illustrates a third alternative structure of the first embodiment of the present disclosure. Following the arrow A3 from the completion of vertical transistors by those in box T of FIG. 2M, etch-stop layer 220 is disposed (step 270 in box S of FIG. 2M) on gate 212 and etched back (step 271 in box S of FIG. 2M) anisotropically with a sufficient over-etch to expose a top portion of semiconductor pillars 204. Then, the process follows arrow B2 of FIG. 2M to continue with the formation of storage capacitors. At step 282 for etching ILD 230 with a capacitor mask (not shown), the recipe need not be a timed etch but may employ an endpoint scheme because the recipe can be chosen to be selective to, and stop on, etch-stop layer 220.

FIG. 2L illustrates a fourth alternative structure of the first embodiment of the present disclosure. At least one mesh layer 239 may be disposed around a small portion of the cup exterior, with the topmost mesh layer formed typically at a higher position than midway between the top and bottom of the internal electrode, in order to support the internal electrode and prevent it from toppling. The risk of toppling of the internal electrode is high when ILD 230 is removed from the cup exterior of the internal electrode. If ILD 230 is not removed or is only slightly removed from the cup exterior so as to make a structure like FIG. 2J, however, a mesh layer may not be necessary to secure the internal electrode against toppling. The formation of mesh layer is somewhat too complicated to describe briefly. Readers are directed to KR100568733B1, “Capacitor having enhanced structural stability, Method of manufacturing the capacitor, Semiconductor device having the capacitor, and Method of manufacturing the semiconductor device.” It is worthwhile to note that a mesh layer may be incorporated in a structure employing an etch-stop layer, resulting in a hybrid structure between FIG. 2K and FIG. 2L.

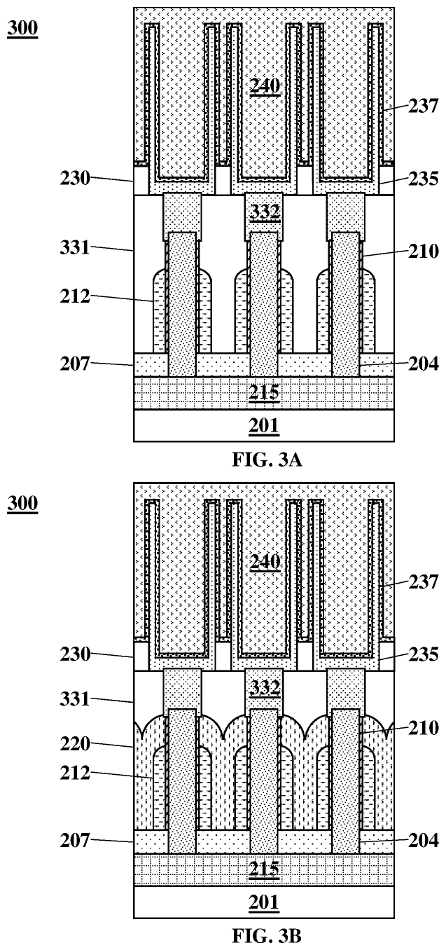

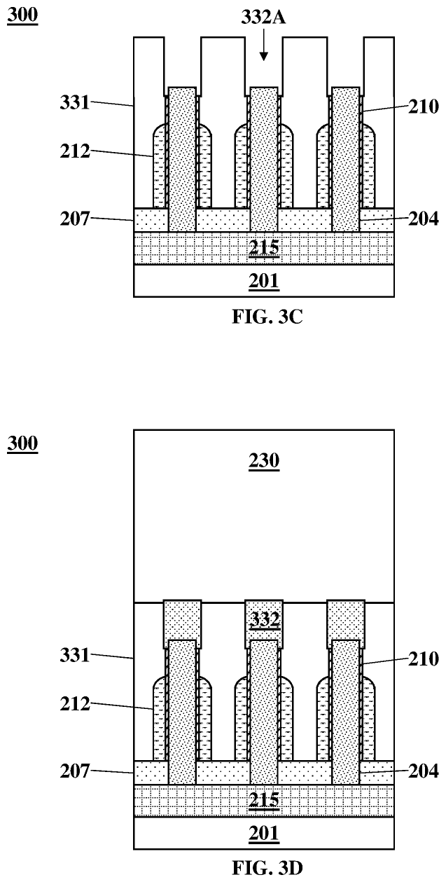

FIG. 3A illustrates a fifth alternative structure of the first embodiment of the present disclosure. A contact plug 332 is disposed between each pair of a vertical transistor and a storage capacitor. The process follows the steps along arrows A2 and C1 in the flowchart of FIG. 2M. Disposition of contact plugs (step 275 of FIG. 2M) involve a few operations in reality. Dispose a first ILD 331, planarize it, etch it with a plug mask (not shown), dispose a metal such as tungsten or copper (typically with a proper barrier metal underneath it), and polish the metal. Storage capacitors are built on contact plugs. A second ILD 230 is disposed (step 280 in box C of FIG. 2M) after forming contact plugs. The construction of the storage capacitors follows the steps in box C of FIG. 2M, and the intermediate structures are similar to those of FIGS. 2F-I except for the contact plugs between the semiconductor pillars and the internal electrodes of storage capacitors.

FIG. 3B illustrate a structure combining the features of contact plugs 332 of FIG. 3A and an etch-stop layer 220 of FIG. 2K. The process follows the steps along arrows A3, B1, and C1 in the flowchart of FIG. 2M. The structure of FIG. 3A or FIG. 3B may be further modified to incorporate one or more mesh layers 239 of FIG. 2L.

FIGS. 3C-D illustrate intermediate structures in a sequence of steps leading to that of FIG. 3A. In FIG. 3C, first ILD 331 is disposed, and holes 332A for contact plugs are formed. The mask (not shown) for the patterning of holes 332A may be derived from capacitor layout 235A (see FIG. 2B), optionally with a size manipulation, at least in bit-line direction. After forming holes 332A, a metal layer (not shown) is disposed and polished until the upper surface of first ILD 331 is exposed and contact plugs 332 are confined within holes 332A. The metal layer may be tungsten or copper, typically with an underlying layer of barrier metal. Subsequently, a second ILD 230 is disposed (the first operation in box C of FIG. 2M), resulting in the structure of FIG. 3D. Then the steps leading to intermediate structures similar to those of FIGS. 2F-I are performed. The disposition of plate electrode (the last operation in box C of FIG. 2M) completes the formation of storage capacitors of this fifth alternative of the first embodiment of the present disclosure.

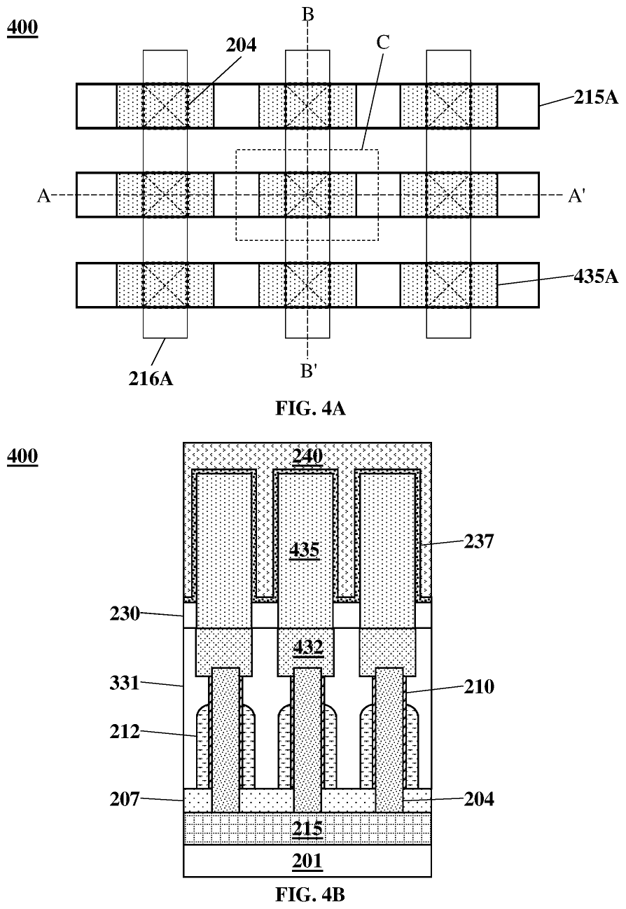

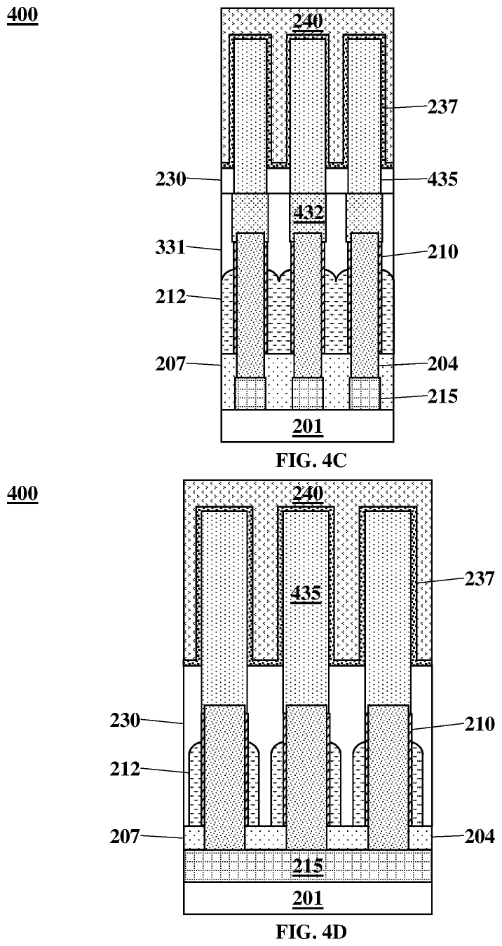

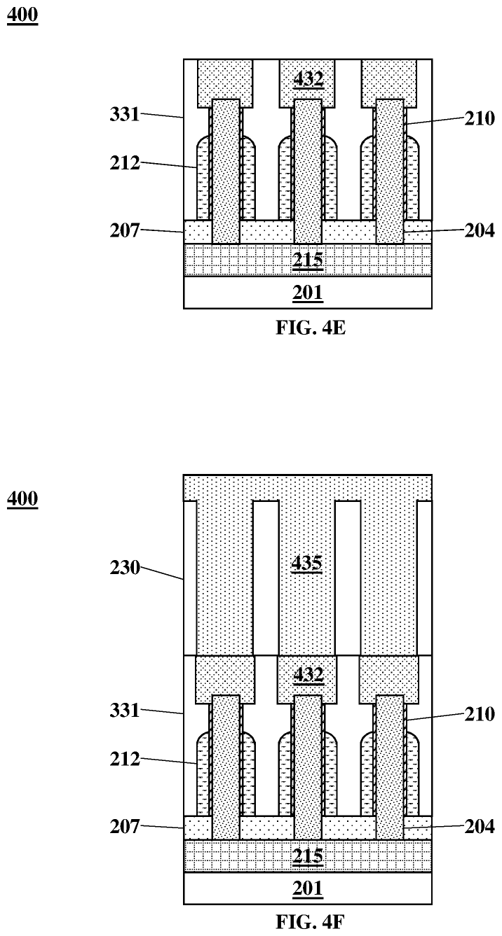

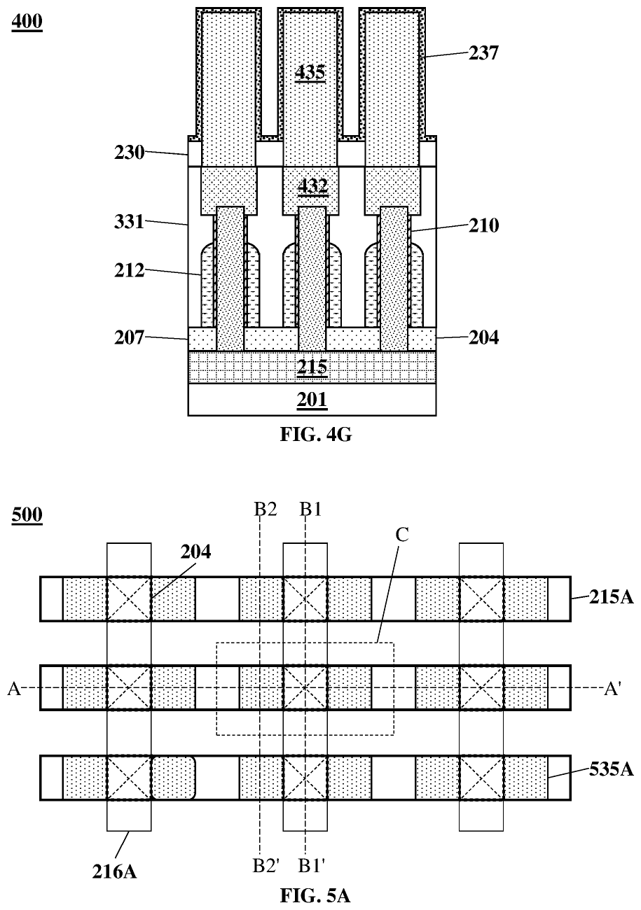

FIGS. 4A-G illustrate a second embodiment of the present disclosure. The internal electrode of storage capacitors is in the shape of a pillar, different from the cup-like shape of the first embodiment. The layout for the second embodiment is identical to that for the first embodiment (compare FIG. 4A against FIG. 2B). A distinction is attempted in FIG. 4A by labeling each storage capacitor with 435A in contrast to 235A of FIG. 2B. The labels are to highlight their different shapes shown in subsequent vertical cross-sectional views. Box C of FIG. 4A illustrates a unit cell having an area of 6 F² with capacitor layout 435A drawn at 2.0 F by 1.0 F. As in the case of the first embodiment, the cell area may be smaller, such as 5 F² if the capacitor pillar is 1.5 F long in bit-line direction A-A′.

FIG. 4B represent a vertical cross-sectional view of the DRAM structure along line A-A′ of FIG. 4A, while a vertical cross-sectional view along line B-B′ is shown in FIG. 4C. In these cross-sectional views, internal electrode or capacitor pillar 435 of each storage capacitor is in the shape of a rectangle rather than a cup. Although these figures include contact plugs 432 between vertical transistors and storage capacitors, a structure as shown in FIG. 4D without such contact plugs is an alternative of the second embodiment. Other alternatives such as those like FIGS. 2K-L incorporating etch-stop layer 220 and/or mesh layer 239 are considered covered within the scope of the second embodiment. Another feature shown in FIG. 4D is the widening of semiconductor pillars along bit-line direction. The absence of contact plugs and the widened semiconductor pillars may not necessarily be in one alternative. Contact plugs may be disposed on widened semiconductor pillars, or storage capacitors may stand directly on semiconductor pillars of a minimum geometry without intervening contact plugs.

FIGS. 4E-G illustrate intermediate structures in a sequence of process steps resulting in those of FIGS. 4B-C. In FIG. 4E, contact plugs 432 are disposed in a dielectric layer 331, in the manner described in reference to FIGS. 3C-D. In FIG. 4F, an ILD 230 is disposed over contact plugs 432 and dielectric layer 331, and patterned to accommodate internal electrode of the storage capacitors, with the steps described in reference to FIG. 2F. Then, the resulting capacitor holes (not shown) like those of 235B in FIG. 2F is filled with a material for capacitor pillars 435 serving as internal electrodes of the storage capacitors. The capacitor pillar material is partly etched back until the top surface of ILD 230 is exposed. These operations involved in the formation of capacitor pillars 435 are analogous to those involved in the formation of contact plugs 432. ILD 230 is then etched down to a bottom portion of the internal electrode. With the subsequent disposition of capacitor dielectric 237, an intermediate structure of FIG. 4G results. Disposition of plate electrode 240 completes the construction of storage capacitors as in FIGS. 4B-C.

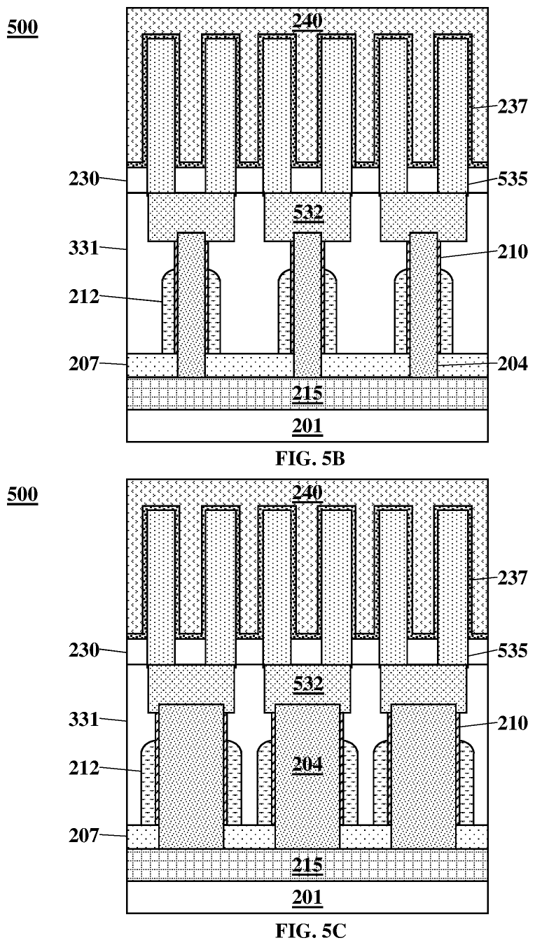

FIGS. 5A-C illustrate a structure in accordance with a third embodiment of the present disclosure. Each memory cell has two capacitor pillars. FIG. 5A illustrates a simplified layout view of the memory cells. In contrast to FIG. 2B and FIG. 4A, a unit cell indicated by box C of FIG. 5A has two instances of capacitor layout 535A which are not directly above semiconductor pillar 204. The cell size as depicted in FIG. 5A is 8 F². If storage capacitors in this embodiment is rectangular in a layout view, they will get elongated along bit-line direction and stay at the minimum width of 1.0 F along word-line direction. The cell size will grow in proportion to the elongation along bit-line direction. For example, if each capacitor pillar grows to 1.5 F, the cell size would become 10 F².

When cut vertically along line A-A′ (i.e. along bit-line direction), the structure looks like that of FIG. 5B. The cross section along word-line direction would be exactly like that of FIG. 4C, with the vertical transistors cut along line B1-B1′ of FIG. 5A and the storage capacitors cut along line B2-B2′. Process flow for the third embodiment is identical to that of the second embodiment with contact plugs employed between semiconductor pillars and storage capacitors. In the third embodiment, contact plugs are usually required to ensure connection of capacitor pillars to semiconductor pillars even in the event of a worst-case misalignment. FIG. 5C shows an alternative structure, having the semiconductor pillars maximally widened along bit-line direction within the space required to accommodate the two capacitor pillars per cell. When the semiconductor pillars are made so wide, contact plugs 532 may not be necessary and capacitor pillars 535 may be directly disposed on semiconductor pillars 204. The semiconductor pillars may be widened by a lesser amount than shown in FIG. 5C in favor of a lesser word-line coupling. It is also worthwhile to mention that etch-stop layer 220 of FIG. 2K or FIG. 3B may be disposed over gate 212 before disposing contact plugs 532 or capacitor pillars 535 on semiconductor pillars 204. Mesh layer 239 of FIG. 2L may be disposed on a small portion of the sidewall of capacitor pillars to prevent toppling of the capacitor pillars.

As used throughout the present disclosure, the word “may” is used in a permissive sense (i.e., meaning “having the potential to”), rather than a mandatory sense (i.e., meaning “must” or “required to”). Similarly, the words “include,” “including,” and “includes” mean “including, but not limited to” the listed item(s).

The foregoing descriptions of specific embodiments of the present disclosure have been presented for purposes of illustration and description. The embodiments were chosen and described in order to explain the principles of the invention and its practical application in the best way, and thereby enable others skilled in the art to best utilize the invention and various embodiments with various modifications as are suited to the particular use contemplated. They are not intended to be exhaustive or to limit the invention to the precise forms disclosed. Many modifications, variations, and rearrangements are possible in light of the above teaching without departing from the broader spirit and scope of the various embodiments. For example, they can be in different sequences than the exemplary ones described herein, e.g., in a different order. One or more additional new elements or steps may be inserted within the existing structures or methods or one or more elements or steps may be abbreviated or eliminated, according to a given application, so long as substantially equivalent results are obtained. Accordingly, structures and methods construed in accordance with the principle, spirit, and scope of the present invention may well be embraced as exemplarily described herein. It is intended that the scope of the invention be defined by the Claims appended hereto and their equivalents.

I/We claim:

1. A DRAM cell, comprising:
a vertical transistor;
a storage capacitor having a rectangular shape in a horizontal cross section; and wherein:
said vertical transistor serves as a DRAM access switch; and
said storage capacitor is conductively coupled to a top doping region of said vertical transistor.

2. The DRAM cell of claim 1, wherein:
said storage capacitor is in contact with a sidewall of a top portion of said top doping region of said vertical transistor.

3. The DRAM cell of claim 1, wherein:
said rectangular shape of said storage capacitor has an aspect ratio of at least 1.5 in said horizontal cross section.

4. The DRAM cell of claim 1, wherein said storage capacitor comprises:
an internal electrode disposed over said top doping region of said vertical transistor;
a capacitor dielectric disposed on said internal electrode;
a plate electrode disposed on said capacitor dielectric; and wherein:
said internal electrode is conductively coupled to said top doping region of said vertical transistor.

5. The DRAM cell of claim 4, wherein:
said internal electrode has a cup shape in a vertical cross section.

6. The DRAM cell of claim 5, wherein:
said capacitor dielectric is disposed on an external surface of said cup shape of said internal electrode down to a bottom portion of said external surface as well as an internal surface of said cup shape.

7. The DRAM cell of claim 4, wherein:
said internal electrode has a pillar shape in a vertical cross section.

8. The DRAM cell of claim 1, wherein said vertical transistor comprises:
a semiconductor pillar;
a gate dielectric disposed on at least a portion of said semiconductor pillar;
a gate surrounding a middle portion of said semiconductor pillar on said gate dielectric; and wherein:
said storage capacitor is conductively coupled to a top doping region of said semiconductor pillar but is separate from said gate of said vertical transistor; and
said top doping region of said semiconductor pillar constitutes said top doping region of said vertical transistor.

9. The DRAM cell of claim 8, wherein:
said semiconductor pillar has a circular shape in a second horizontal cross section.

10. The DRAM cell of claim 8, wherein:
said semiconductor pillar has a rectangular shape in a second horizontal cross section.

11. The DRAM cell of claim 10, wherein:
said rectangular shape of said semiconductor pillar has an aspect ratio of at least 1.5 in said second horizontal cross section.

12. The DRAM cell of claim 8, wherein said semiconductor pillar comprises:
a first region of a first doping type in said middle portion of said semiconductor pillar under said gate;
a second region of a second doping type in a top portion of said semiconductor pillar, extending into said middle portion from said top portion, and contiguous with said first region; and
a third region of said second doping type in a bottom portion of said semiconductor pillar, extending into said middle portion from said bottom portion, and contiguous with said first region.

13. The DRAM cell of claim 8, wherein:
said semiconductor pillar comprises a single-crystalline semiconductor material.

14. The DRAM cell of claim 8, wherein:
said semiconductor pillar comprises a poly-crystalline semiconductor material.

15. The DRAM cell of claim 1, further comprising:
an etch-stop layer disposed over, and up to below a top portion of said top doping region of, said vertical transistor; and wherein:
said storage capacitor is disposed over said etch-stop layer.

16. The DRAM cell of claim 1, further comprising:
at least one mesh layer disposed on a portion of an exterior surface of said rectangular shape of, and supporting, said storage capacitor.

17. The DRAM cell of claim 1, further comprising:
a contact plug disposed on said top doping region of said vertical transistor; and wherein:
said storage capacitor is disposed on said contact plug.

18. The DRAM cell of claim 17, wherein:
said contact plug is in contact with a sidewall of a top portion of said top doping region of said vertical transistor.

19. A DRAM module, comprising:
a plurality of DRAM cells arranged in an array;
a plate electrode; and wherein:
each of said plurality of DRAM cells comprises:
a vertical transistor; and
a storage capacitor having a rectangular shape in a horizontal cross section;
said array has a bit-line direction and a word-line direction;
said bit-line direction and said word-line direction are perpendicular to each other;
said vertical transistor serves as a DRAM access switch in each of said plurality of DRAM cells;
said storage capacitor is conductively coupled to a top doping region of said vertical transistor in each of said plurality of DRAM cells;
said plate electrode is disposed on said storage capacitor in each of said plurality of DRAM cells; and
said plate electrode is continuous across said plurality of DRAM cells in both said bit-line direction and said word-line direction.

20. The DRAM module of claim 19, wherein:
said storage capacitor is in contact with a sidewall of a top portion of said top doping region of said vertical transistor in each of said plurality of DRAM cells.

21. The DRAM module of claim 19, wherein:
said rectangular shape of said storage capacitor has an aspect ratio of at least 1.5 times and is longer than wide in each of said plurality of DRAM cells.

22. The DRAM module of claim 19, wherein said storage capacitor in each of said plurality of DRAM cells comprises:
an internal electrode disposed over said vertical transistor;
a capacitor dielectric disposed on said internal electrode; and wherein:
said plate electrode is disposed on said capacitor dielectric in each of said plurality of DRAM cells; and
said internal electrode is conductively coupled to said top doping region of said vertical transistor in each of said plurality of DRAM cells.

23. The DRAM module of claim 22, wherein:
said internal electrode has a cup shape in a vertical cross section in each of said plurality of DRAM cells.

24. The DRAM module of claim 23, wherein:
said capacitor dielectric is disposed on an external surface of said cup shape of said internal electrode down to a bottom portion of said external surface as well as an internal surface of said cup shape in each of said plurality of DRAM cells.

25. The DRAM module of claim 22, wherein:
said internal electrode has a pillar shape in a vertical cross section in each of said plurality of DRAM cells.

26. The DRAM module of claim 19, wherein:
said rectangular shape of said storage capacitor stretches longer in said bit-line direction than in said word-line direction in each of said plurality of DRAM cells.

27. The DRAM module of claim 19, wherein said vertical transistor in each of said plurality of DRAM cells comprises:
a semiconductor pillar;
a gate dielectric disposed on at least a portion of said semiconductor pillar;
a gate surrounding a middle portion of said semiconductor pillar on said gate dielectric; and wherein:
said gate is connected in said word-line direction across said plurality of DRAM cells but is separated in said bit-line direction between said plurality of DRAM cells;
said gate connected across said plurality of DRAM cells in said word-line direction collectively constitutes a plurality of word lines;
said storage capacitor is conductively coupled to a top doping region of said semiconductor pillar but is separate from said gate of said vertical transistor in each of said plurality of DRAM cells; and
said top doing region of said semiconductor pillar constitutes said top doping region of said vertical transistor in each of said plurality of DRAM cells.

28. The DRAM module of claim 27, wherein:
a space between said semiconductor pillars of immediate neighbors of said plurality of DRAM cells in said word-line direction is sufficiently narrow to result in connection of said vertical transistors at said gate; and
a space between said semiconductor pillars of immediate neighbors of said plurality of DRAM cells in said bit-line direction is sufficiently wide to result in separation of said vertical transistors at said gate.

29. The DRAM module of claim 27, wherein:
said semiconductor pillar of said vertical transistor in each of said plurality of DRAM cells has a circular shape in a second horizontal cross section.

30. The DRAM module of claim 27, wherein:
said semiconductor pillar of said vertical transistor in each of said plurality of DRAM cells has a rectangular shape in a second horizontal cross section.

31. The DRAM module of claim 30, wherein:
said rectangular shape of said semiconductor pillar in each of said plurality of DRAM cells is longer in said bit-line direction than in said word-line direction.

32. The DRAM module of claim 27, wherein said semiconductor pillar of said vertical transistor in each of said plurality of DRAM cells comprises:
a first region of a first doping type in said middle portion of said semiconductor pillar under said gate;
a second region of a second doping type in a top portion of said semiconductor pillar, extending into said middle portion from said top portion, and contiguous with said first region; and
a third region of said second doping type in a bottom portion of said semiconductor pillar, extending into said middle portion from said bottom portion, and contiguous with said first region.

33. The DRAM module of claim 27, wherein:
said semiconductor pillar of said vertical transistor in each of said plurality of DRAM cells comprises a single-crystalline semiconductor material.

34. The DRAM module of claim 27, wherein:
said semiconductor pillar of said vertical transistor in each of said plurality of DRAM cells comprises a poly-crystalline semiconductor material.

35. The DRAM module of claim 19, further comprising:
an etch-stop layer disposed over, and up to below a top portion of said top doping region of, said vertical transistor in each of said plurality of DRAM cells; and wherein:
said storage capacitor is disposed over said etch-stop layer in each of said plurality of DRAM cells.

36. The DRAM module of claim 19, further comprising:
at least one mesh layer disposed on a portion of an exterior surface of said rectangular shape of, and supporting, said storage capacitor in each of said plurality of DRAM cells; and wherein:
said at least one mesh layer is continuous across said plurality of DRAM cells in both said bit-line direction and said word-line direction.

37. The DRAM module of claim 19, further comprising:
a plurality of contact plugs; wherein:
each of said plurality of DRAM cells has one of said plurality of contact plugs disposed on said top doping region of said vertical transistor; and
said storage capacitor is disposed on said one of said plurality of contact plugs in each of said plurality of DRAM cells.

38. The DRAM module of claim 37, wherein:
said one of said plurality of contact plugs in each of said plurality of DRAM cells is in contact with a sidewall of a top portion of said top doping region of said vertical transistor.

39. The DRAM module of claim 19, further comprising:
a DRAM control circuitry for a DRAM operation disposed underneath said plurality of DRAM cells;
a plurality of bit lines, each stretching in said bit-line direction across said plurality of DRAM cells;
a plurality of word lines, each stretching in said word-line direction across said plurality of DRAM cells; and wherein:
each of said plurality of DRAM cells has only one of said plurality of bit lines passing through it;
each of said plurality of DRAM cells has only one of said plurality of word lines passing through it; and
said DRAM control circuitry is coupled to said plurality of bit lines, said plurality of word lines, and said plate electrode for said DRAM operation.

40. The DRAM module of claim 39, wherein:
said vertical transistor is formed on said only one of said plurality of bit lines in each of said plurality of DRAM cells.

41. A DRAM cell, comprising:
a substrate;
a vertical transistor;
a pair of storage capacitors;
a plate electrode coupling said pair of storage capacitors; and wherein:
said vertical transistor comprises:
a semiconductor pillar disposed over said substrate;
a gate dielectric disposed on at least a portion of said semiconductor pillar; and
a gate surrounding a middle portion of said semiconductor pillar on said gate dielectric;
each of said pair of storage capacitors comprises:
a capacitor pillar; and
a capacitor dielectric disposed on said capacitor pillar;
said plate electrode is disposed on said capacitor dielectric of each of said pair of storage capacitors and surrounds said capacitor pillar of each of said pair of storage capacitors down to a bottom portion of said capacitor pillar of each of said pair of storage capacitors; and
said capacitor pillar of each of said pair of storage capacitors is conductively coupled to said semiconductor pillar of said vertical transistor and is separated from said gate of said vertical transistor.

42. The DRAM cell of claim 41, wherein:
said capacitor pillar of each of said pair of storage capacitors is in contact with a top portion of a sidewall of said semiconductor pillar.

43. The DRAM cell of claim 41, wherein:
said capacitor pillar of each of said pair of storage capacitors has a rectangular shape in a horizontal cross section.

44. The DRAM cell of claim 43, wherein:
said rectangular shape of said capacitor pillar has an aspect ratio of at least 1.5 times in said horizontal cross section.

45. The DRAM cell of claim 41, wherein:
said semiconductor pillar has a circular shape in a horizontal cross section.

46. The DRAM cell of claim 41, wherein:
said semiconductor pillar has a rectangular shape in a horizontal cross section.

47. The DRAM cell of claim 46, wherein:
said rectangular shape of said semiconductor pillar has an aspect ratio of at least 1.5 in said horizontal cross section.

48. The DRAM cell of claim 41, wherein said semiconductor pillar comprises:
a first region of a first doping type in said middle portion of said semiconductor pillar under said gate;
a second region of a second doping type in a top portion of said semiconductor pillar, extending into said middle portion from said top portion, and contiguous with said first region;
a third region of said second doping type in a bottom portion of said semiconductor pillar, extending into said middle portion from said bottom portion, and contiguous with said first region.

49. The DRAM cell of claim 41, wherein:
said semiconductor pillar comprises a single-crystalline semiconductor material.

50. The DRAM cell of claim 41, wherein:
said semiconductor pillar comprises a poly-crystalline semiconductor material.

51. The DRAM cell of claim 41, further comprising:
an etch-stop layer disposed over said gate up to below a top portion of said semiconductor pillar; and wherein:
said capacitor pillar of each of said pair of storage capacitors is disposed over said etch-stop layer.

52. The DRAM cell of claim 41, further comprising:
at least one mesh layer disposed on a portion of an exterior surface of each of, and supporting, said pair of storage capacitors.

53. The DRAM cell of claim 41, further comprising:
a contact plug disposed on said semiconductor pillar; and wherein:
said capacitor pillar of each of said pair of storage capacitors is disposed on said contact plug.

54. A DRAM module comprising:
a substrate;
a plurality of DRAM cells arranged in an array;
a plate electrode; and wherein:
said array has a word-line direction and a bit-line direction such that said word-line direction and said bit-line direction are perpendicular to each other;
each of said plurality of DRAM cells comprises:
a bit line disposed over said substrate;
a vertical transistor disposed on said bit line; and
a storage capacitor disposed over said vertical transistor;
said vertical transistor in each of said plurality of DRAM cells comprises:
a semiconductor pillar disposed on said bit line;
a gate dielectric disposed on at least a portion of said semiconductor pillar; and
a gate surrounding a middle portion of said semiconductor pillar on said gate dielectric;
said storage capacitor in each of said plurality of DRAM cells comprises:
a pair of capacitor pillars disposed over said semiconductor pillar; and
a capacitor dielectric disposed on said pair of capacitor pillars;
said bit line in each of said plurality of DRAM cells is continuous across said plurality of DRAM cells in said bit-line direction but is separated between said plurality of DRAM cells in said word-line direction;
said bit line stretching in said bit-line direction across said plurality of DRAM cells collectively constitutes a plurality of bit lines;
said gate is connected in said word-line direction across said plurality of DRAM cells but is separated in said bit-line direction between said plurality of DRAM cells;
said gate connected across said plurality of DRAM cells in said word-line direction collectively constitutes a plurality of word lines;
said pair of capacitor pillars of said storage capacitor are conductively coupled to said semiconductor pillar but are separated from said gate of said vertical transistor in each of said plurality of DRAM cells;
said plate electrode is disposed on said capacitor dielectric of said storage capacitor in each of said plurality of DRAM cells; and
said plate electrode is continuous across said plurality of DRAM cells in both said bit-line direction and said word-line direction.

55. The DRAM module of claim 54, wherein:
said pair of capacitor pillars of said storage capacitor are in contact with a top portion of a sidewall of said semiconductor pillar in each of said plurality of DRAM cells.

56. The DRAM module of claim 54, wherein:
each of said pair of capacitor pillars has a rectangular shape in a horizontal cross section in each of said plurality of DRAM cells.

57. The DRAM module of claim 56, wherein:
said rectangular shape of each of said pair of capacitor pillars has an aspect ratio of at least 1.5 times and is longer in said bit-line direction than in said word-line direction in each of said plurality of DRAM cells.

58. The DRAM module of claim 54, wherein:
said semiconductor pillar in each of said plurality of DRAM cells has a circular shape in a horizontal cross section.

59. The DRAM module of claim 54, wherein:
said semiconductor pillar in each of said plurality of DRAM cells has a rectangular shape in a horizontal cross section.

60. The DRAM module of claim 59, wherein:
said rectangular shape of said semiconductor pillar in each of said plurality of DRAM cells has an aspect ratio of at least 1.5 times and is longer in said bit-line direction than in said word-line direction.

61. The DRAM module of claim 54, wherein said semiconductor pillar in each of said plurality of DRAM cells comprises:
a first region of a first doping type in said middle portion of said semiconductor pillar under said gate;
a second region of a second doping type in a top portion of said semiconductor pillar, extending into said middle portion from said top portion, and contiguous with said first region; and
a third region of said second doping type in a bottom portion of said semiconductor pillar, extending into said middle portion from said bottom portion, and contiguous with said first region.

62. The DRAM module of claim 54, wherein:
said semiconductor pillar in each of said plurality of DRAM cells comprises a single-crystalline semiconductor material.

63. The DRAM module of claim 54, wherein:
said semiconductor pillar in each of said plurality of DRAM cells comprises a poly-crystalline semiconductor material.

64. The DRAM module of claim 54, further comprising:
an etch-stop layer disposed over said gate up to below a top portion of said semiconductor pillar in each of said plurality of DRAM cells; and wherein:
said pair of capacitor pillars of said storage capacitor in each of said plurality of DRAM cells are disposed over said etch-stop layer.

65. The DRAM module of claim 54, further comprising:
at least one mesh layer disposed on a portion of an exterior surface of each of, and supporting, said pair of capacitor pillars in each of said plurality of DRAM cells.

66. The DRAM module of claim 54, further comprising:
a circuitry for a DRAM operation is constructed in said substrate; and wherein:
said circuitry communicates with said plurality of bit lines, said plurality of word lines, and said plate electrode for said DRAM operation.

67. The DRAM module of claim 54, further comprising:
a plurality of contact plugs; wherein:
each of said plurality of DRAM cells has one of said plurality of contact plugs disposed on said semiconductor pillar; and
said pair of capacitor pillars of said storage capacitor are disposed on said one of said plurality of contact plugs in each of said plurality of DRAM cells.

68. The DRAM module of claim 67, wherein:
said one of said plurality of contact plugs in each of said plurality of DRAM cells is in contact with a sidewall of a top portion of said semiconductor pillar.
